(19) United States
(12) Patent Application Publication
(10) Pub. No.: US 2026/0040480 A1
(43) Pub. Date: Feb. 5, 2026

(54) NETWORK SWITCH WITH INCREASED REAR PORT DENSITY FOR PLUGGABLE TRANSCEIVERS

(71) Applicant: Dell Products L.P., Round Rock, TX (US)

(72) Inventors: Padmanabhan Narayanan, Chennai (IN); Shree Rathinasamy, Georgetown, TX (US); Robert Neal Beard, Austin, TX (US)

(21) Appl. No.: 18/794,427

(22) Filed: Aug. 5, 2024

(51) Int. Cl. H05K 7/20

(52) U.S. Cl. CPC H05K 7/20172

(57) ABSTRACT

A network switch including a motherboard that includes at least one pair of rear ports disposed at a rear thereof, the at least one pair of rear ports including a left rear port and a right rear port. The network switch further including at least one fan slot disposed behind the motherboard and through which the at least one pair of rear ports is accessible. Also proposed are a fan module design that can accommodate the cables from the at least one pair of rear ports, as well as an air dam base design for thermal sealing.

### BACKGROUND

In tune with the surge in demand from high performance computing (HPC) and artificial intelligence/machine learning (AI/ML) applications, vendors have been able to double the bandwidth of network processing units (NPUs) ˜every 2 years, as well as increase the radix while also significantly lowering power. While port breakout is a viable option to utilize the high radix of these NPUs, they are still limited by the number of switch ports that may be populated in a front panel of the network switch.

### SUMMARY

In general, in one aspect, embodiments described herein relate to a network switch. The network switch includes: a motherboard, including: at least one pair of rear ports disposed at a rear thereof. The at least one pair of rear ports includes: a left rear port and a right rear port. The network switch further includes: at least one fan slot disposed behind the motherboard and through which the at least one pair of rear ports is accessible.

In general, in one aspect, embodiments described herein relate to a method for transforming an air dam base into a cable sealed, top and bottom plugged air dam base. The method includes: inserting an air dam base bottom half plug into the air dam base to obtain a bottom plugged air dam base; routing a transceiver cable through the bottom plugged air dam base to obtain a cable routed, bottom plugged air dam base; and inserting an air dam base top half plug into the cable routed, bottom plugged air dam base to obtain the cable sealed, top and bottom plugged air dam base.

Other aspects of the embodiments described herein will be apparent from the following description and the appended claims.

### BRIEF DESCRIPTION OF DRAWINGS

Certain embodiments described herein will be described with reference to the accompanying drawings. However, the accompanying drawings illustrate only certain aspects or implementations of the embodiments by way of example and are not meant to limit the scope of the claims.

FIG. 1 shows a network switch in accordance with one or more embodiments described herein.

FIGS. 2A-2C show isometric, front, and rear views of a caged fan module in accordance with one or more embodiments described herein.

FIG. 3 shows a keyed assembly of a cable sealed, top and bottom plugged air dam base in accordance with one or more embodiments described herein.

FIG. 4A shows a fan slot occupation process in accordance with one or more embodiments described herein.

FIG. 4B shows an occupied fan slot in accordance with one or more embodiments described herein.

### DETAILED DESCRIPTION

Specific embodiments will now be described with reference to the accompanying figures.

In the below description, numerous details are set forth as examples of embodiments described herein. It will be understood by those skilled in the art (who also have the benefit of this Detailed Description) that one or more embodiments of embodiments described herein may be practiced without these specific details, and that numerous variations or modifications may be possible without departing from the scope of the embodiments described herein. Certain details known to those of ordinary skill in the art may be omitted to avoid obscuring the description.

In the below description of the figures, any component described with regard to a figure, in various embodiments described herein, may be equivalent to one or more like-named components described with regard to any other figure. For brevity, descriptions of these components may not be repeated with regard to each figure. Thus, each and every embodiment of the components of each figure is incorporated by reference and assumed to be optionally present within every other figure having one or more like-named components. Additionally, in accordance with various embodiments described herein, any description of the components of a figure is to be interpreted as an optional embodiment, which may be implemented in addition to, in conjunction with, or in place of the embodiments described with regard to a corresponding like-named component in any other figure.

Throughout the application, ordinal numbers (e.g., first, second, third, etc.) may be used as an adjective for an element (i.e., any noun in the application). The use of ordinal numbers is not to imply or create any particular ordering of the elements, nor to limit any element to being only a single element unless expressly disclosed, such as by the use of the terms “before”, “after”, “single”, and other such terminology. Rather, the use of ordinal numbers is to distinguish between the elements. By way of an example, a first element is distinct from a second element, and the first element may encompass more than one element and succeed (or precede) the second element in an ordering of elements.

Throughout this application, elements of figures may be labeled as A to N. As used herein, the aforementioned labeling means that the element may include any number of items and does not require that the element include the same number of elements as any other item labeled as A to N. For example, a data structure may include a first element labeled as A and a second element labeled as N. This labeling convention means that the data structure may include any number of the elements. A second data structure, also labeled as A to N, may also include any number of elements. The number of elements of the first data structure and the number of elements of the second data structure may be the same or different.

As used herein, the phrase operatively connected, or operative connection, means that there exists between elements/components/devices a direct or indirect connection that allows the elements to interact with one another in some way. For example, the phrase ‘operatively connected’ may refer to any direct (e.g., wired directly between two devices or components) or indirect (e.g., wired and/or wireless connections between any number of devices or components connecting the operatively connected devices) connection. Thus, any path through which information may travel may be considered an operative connection.

In general, embodiments described herein relate to a network switch with increased rear port density for pluggable transceivers. Particularly, in tune with the surge in demand from high performance computing (HPC) and artificial intelligence/machine learning (AI/ML) applications, vendors have been able to double the bandwidth of network processing units (NPUs) ˜every 2 years, as well as increase the radix while also significantly lowering power. While port breakout is a viable option to utilize the high radix of these NPUs, they are still limited by the number of switch ports that may be populated in a front panel of the network switch (usually called I/O side).

The power supply unit (PSU) side of a network switch typically has 2 PSUs (on the extreme left & right ends). A one rack unit (1RU) network switch has anywhere between 5 to 7 fan tray modules, which are field replaceable from the rear. It is to be noted that fan trays have one of the lowest field incident rates (FIR) on a network switch. FIR rates of a transceiver are also low with typical useful lifetimes averaging 5 years. In existing network switch designs, there is sufficient space between the network switch (mother) board and the fan controller boards. It is therefore possible to extend the network switch (mother) board to accommodate additional switch ports that are accessible (for transceiver/cable insertion/removal) from the rear through the fan module bays. Transceiver/cable replacement in this proposal can take a couple of minutes and therefore removing (and later replacing) fan modules can be done in a controlled fashion with brief thermal impact.

Embodiments described herein thus propose a novel network switch design with rear switch ports, a corresponding fan module design that can accommodate the cables from the rear switch ports, as well as an air dam base design for thermal sealing. Replacement of any transceivers/cables is made possible by first unplugging the corresponding fan module, performing the replacement, and then plugging in the fan module as illustrated and described in further detail herein.

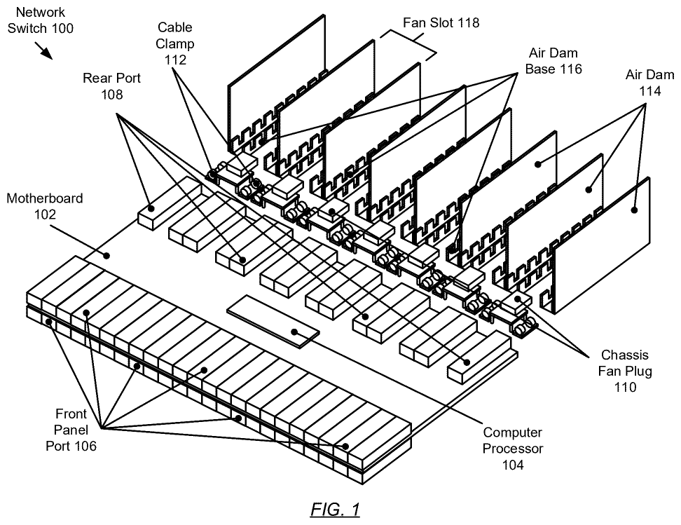

FIG. 1 shows a network switch in accordance with one or more embodiments described herein. The network switch (100) represents a physical, high-performance device configured to connect network servers, storage devices, and other network appliances within enterprise (e.g., on-premises and/or cloud computing infrastructure) environments. Said connection between enterprise environment elements may be implemented over one or more networks (e.g., local area networks (LANs), wide area networks (WANs) such as the Internet, mobile networks, etc.).

In one or many embodiment(s) described herein, the network switch (100) includes a chassis (not shown) representing, and thus serving as, a structural frame or housing within which other (internal) components of the network switch (100) may be enclosed and/or to which one or more of said other components may be affixed or mounted. The chassis may be assembled from multiple panels (not shown) that may be fastened together using any number and any form of mechanical fasteners (e.g., screws, bolts, latches, rivets, etc.) (not shown). Further, the chassis may be constructed of lightweight, yet rigid and durable materials such as, for example, steel, aluminum, plastics, carbon fiber, composites, or any combination thereof.

In one or many embodiment(s) described herein, the above-mentioned other (internal) components of the network switch (100) include a motherboard (102), a computer processor (104), multiple front panel ports (106), multiple rear ports (108), and multiple fan slots (118). Each of these network switch (100) (internal) components is described below.

In one or many embodiment(s) described herein, the motherboard (102) represents a physical printed circuit board (PCB) configured to interconnect, facilitate communications amongst, and distribute power to one or more electronic and/or electro-mechanical components (e.g., computer processor (104), front and rear panel ports (106, 108), power supplies (not shown), fan modules (not shown), storage/memory devices (not shown), etc.) of the network switch (100). One of ordinary skill, however, will appreciate that the motherboard (102) may perform other functionalities without departing from the scope of the embodiments described herein.

In one or many embodiment(s) described herein, the computer processor (104) represents an integrated circuit configured to process computer readable instructions. Said computer readable instructions may govern a behavior, or implement any specified functionalities, of the network switch (100). By way of examples, the computer processor (104) may be implemented as a central processing unit (CPU), a network processing unit (NPU), a field programmable gate array (FPGA), an application specific integrated circuit (ASIC), or any combination thereof.

In one or many embodiment(s) described herein, any front panel port (106) represents a communications receptacle mounted on a front-facing portion of the motherboard (102) and operatively connected to the computer processor (104). Any front panel port (106), further, may at least in part be exposed or accessible through a front panel (not shown) of the chassis (not shown) of the network switch (100), where any front panel port (106) may be configured to receive a pluggable transceiver (not shown). Any front panel port (106) provides or includes either fiber-optic or copper links, which mate with counterpart fiber-optic or copper links, respectively, of the received pluggable transceiver. Said pluggable transceiver may provide or include a connector (e.g., multi-fiber push on (MPO) fiber-optic link connector, little/local connector (LC) fiber-optic link connector, registered jack (RJ)-45 copper link connector, etc.) for terminating one end of a compatible transceiver cable (not shown). Any front panel port (106), moreover, may enable (wired) high-speed telecommunication and/or data communications between the network switch (100) and any number of other enterprise environment systems. By way of an example, any front panel port (106) may be implemented as a small form-factor pluggable (SFP) port, or any derivative thereof.

In one or many embodiment(s) described herein, any rear port (108) represents a communications receptacle mounted on a rear-facing portion of the motherboard (102) and operatively connected to the computer processor (104). Any rear port (108), further, may at least in part be exposed within or accessible through a fan slot (118), where any rear port (108) may be configured to receive a pluggable transceiver (not shown). Any rear port (108) provides or includes either fiber-optic or copper links, which mate with counterpart fiber-optic or copper links, respectively, of the received pluggable transceiver. Said pluggable transceiver may provide or include a connector (e.g., MPO fiber-optic link connector, LC fiber-optic link connector, RJ-45 copper link connector, etc.) for terminating one end of a compatible transceiver cable (not shown). Any rear port (108), moreover, may enable (wired) high-speed telecommunication and/or data communications between the network switch (100) and any number of other enterprise environment systems. By way of an example, any rear port (108) may be implemented as a SFP port, or any derivative thereof.

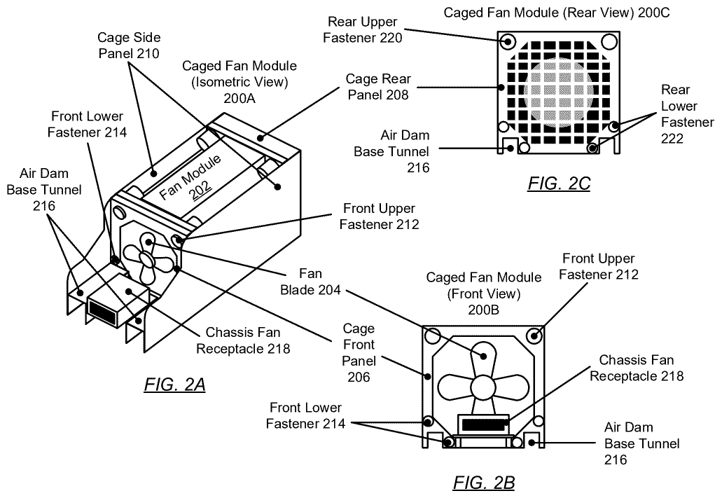

In one or many embodiment(s) described herein, any fan slot (118) represents a bay or a space, which is disposed at the rear of the network switch (100), and is configured to receive or accommodate a fan module (or a caged fan module) (see e.g., FIGS. 2A-2C). Any fan slot (118), furthermore, includes a pair of air dams (114), a pair of air dam bases (116), a chassis fan plug (110), and a pair of cable clamps (112). Each of these fan slot (118) subcomponents is described below.

In one or many embodiment(s) described herein, an air dam (114) represents a barrier that not only functions as a side panel for the fan slot (118) but also serves to prevent airflow leakage between fan slots (118). An air dam (114) may be constructed, for example, of steel sheet, and reflects a height defined by the distance between the bottom and top panels (not shown) of the chassis (not shown) of the network switch (100) as well as a length matching that of any air dam base (116) and any caged air module (not shown). An air dam (114), furthermore, may be erected upright through support from at least one air dam base (116) to which the air dam (114) may be attached and detached.

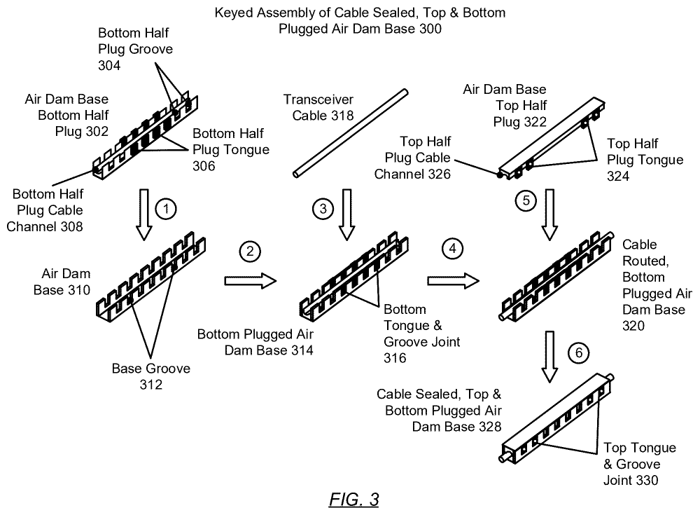

In one or many embodiment(s) described herein, an air dam base (116) represents a physical structure functioning as a foundation or support for an air dam (114), where the air dam base (116) may be affixed to a bottom panel (not shown) of a chassis (not shown) of the network switch (100). An air dam base (116), moreover, may also serve as a passageway through which a transceiver cable (not shown) may be routed along the length of a caged fan module (not shown). The routing of said transceiver cable through an air dam base (116) is illustrated and described in further detail with respect to FIG. 3, below.

In one or many embodiment(s) described herein, the chassis fan plug (110) represents a male connector operatively connected to the computer processor (104) and configured for insertion into a counterpart female connector (e.g., chassis fan receptacle (see e.g., 218, FIGS. 2A-2C)) of a caged fan module (not shown). The chassis fan plug (110), furthermore, may provide or include copper conductors through which fan module power and control signals may propagate in order to operate the caged fan module. The chassis fan plug (110) is disposed between the motherboard (102) and the fan slot (118), and aligns with the fan slot (118). By way of an example, the chassis fan plug (110) may be implemented using a standard board-to-board, right-angle power and signal connector plug.

In one or many embodiment(s) described herein, a cable clamp (112) represents a physical (mechanical) device configured to secure and/or route a transceiver cable (not shown) along a side of the chassis fan plug (110) aligned with the fan slot (118). Accordingly, a cable clamp (112) is disposed at a left or right side of the chassis fan plug (110) as well as between the motherboard (102) and the fan slot (118). A cable clamp (112), furthermore, may route a transceiver cable extending from an air dam base (116) to a rear port (108) (or a transceiver (not shown) inserted into the rear port (108)), where the cable clamp (112), the air dam base (116), and the rear port (108) are all aligned with one another. The cable clamp (112) may be constructed using, for example, steel, aluminum, plastics, carbon fiber, composites, or any combination thereof.

While FIG. 1 shows a configuration of components and/or subcomponents, other network switch (100) configurations may be used without departing from the scope of the embodiments described herein.

For example, in one or many embodiment(s) described herein, any one or more rear ports (108) may each instead be implemented as a co-packaged optics (CPO) port, which may couple directly with a compatible fiber-optic cable (not shown) (i.e., without an intervening transceiver there-between).

FIGS. 2A-2C show isometric, front, and rear views of a caged fan module in accordance with one or more embodiments described herein. The caged fan module (200A, 200B, 200C) represents a fan module (202) at least partially enclosed within a fan cage. The fan cage, in turn, represents, and thus serves as, a structural frame or housing within which the fan module (202) may at least be partially enclosed and/or to which the fan module (202) may, at least in part, be affixed or mounted. The fan cage may be assembled from multiple panels (e.g., cage front panel (206), cage rear panel (208), and cage side panels (210)) that may be fastened together, or to the fan module (202), using any number and any form of mechanical fasteners (e.g., front upper fasteners (212), front lower fasteners (214), rear upper fasteners (220), and rear lower fasteners (222)). The fan cage may serve other functionalities such as, for example, prevent any dust and debris from accumulating directly on the fan blades (204), thereby protecting, as well as facilitating any warranted cleaning of, the fan blades (204). Further, the fan cage may be constructed of lightweight, yet rigid and durable materials such as, for example, steel, aluminum, plastics, carbon fiber, composites, or any combination thereof.

In one or many embodiment(s) described herein, the fan module (202) represents a physical device configured to provide active cooling to one or more (internal) components of the network switch. Active cooling refers to a heat-reducing framework that consumes energy (e.g., electrical power) in order to implement proper heat transfer and airflow circulation. To that extent, the fan module (202) includes functionality to: draw in cool air from the surroundings outside, and at the front of, the network switch; move said cool air over/across one or more (internal) components of the network switch, which thereby absorbs at least a portion of any heat generated by said (internal) component(s) to become hot air;

and expel said hot air from the network switch into the surroundings outside, and at the rear of, the network switch.

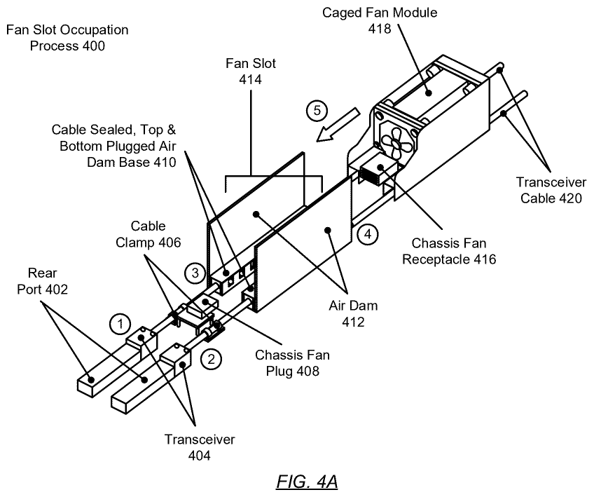

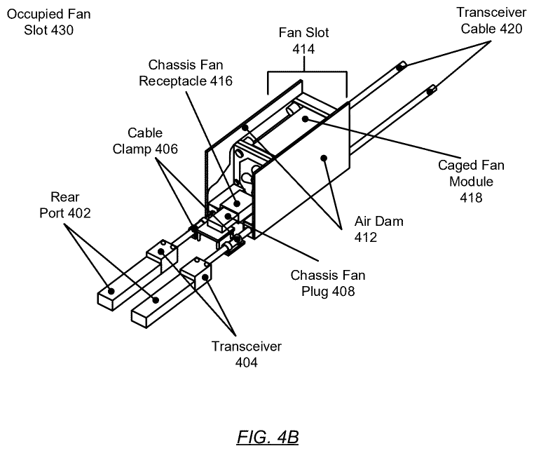

In one or many embodiment(s) described herein, the caged fan module (200A, 200B, 200C) includes a pair (2) of air dam base tunnels (216) disposed at the bottom left and right sides of the caged fan module (200A, 200B, 200C). Specifically, each air dam base tunnel (216) runs along a length of the caged fan module (200A, 200B, 200C) on, and at a one (1) millimeter offset from the edge of, a respective side of the fan module (202). Each air dam base tunnel (216), further, includes an unexposed portion that runs through a combined length of the cage front panel (206), the fan module (202), and the cage rear panel (208), and an exposed portion that extends beyond said combined length up to the front edge of a respective cage side panel (210). Additionally, a cross-section of each air dam base tunnel (216) is square-shaped, where said cross-section is one (1) millimeter taller in height and two (2) millimeters wider (in width) than a cross-section of cable sealed, top and bottom plugged air dam base (see e.g., 328, FIG. 3) on top of which the air dam base tunnel (216) is designed to slide over (see e.g., FIGS. 4A and 4B). The air dam base tunnels (216) subsequently function as passageways through which transceiver cables (not shown) may be routed.

In one or many embodiment(s) described herein, the caged fan module (200A, 200B, 200C) includes a chassis fan receptacle (218) disposed in front of the cage front panel (206) and between the pair (2) of air dam base tunnels (216). The chassis fan receptacle (218) represents a female connector operatively connected to the fan module (202) and configured to receive a counterpart male connector (e.g., chassis fan plug (see e.g., 110, FIG. 1)) through which fan module (202) power and control signals may propagate in order to operate the fan module (202). By way of an example, the chassis fan receptacle (218) may be implemented using a standard board-to-board, right-angle power and signal connector receptacle.

In one or many embodiment(s) described herein, the caged fan module (200A, 200B, 200C) includes a pair of front upper fasteners (212) (e.g., screws) disposed at the upper left and right corners of the cage front panel (206). The front upper fasteners (212), at least in part (i.e., alongside the front lower fasteners (214)), serve to fasten the cage front panel (206) to a front face (not shown) of the fan module (202). Further, by way of example, each front upper fastener (212) may be implemented using a M3×20 screw (defined by 2.9 millimeter diameter and 20 millimeter length).

In one or many embodiment(s) described herein, the caged fan module (200A, 200B, 200C) includes a pair (2) of rear upper fasteners (220) (e.g., screws) disposed at the upper left and right corners of the cage rear panel (208). The rear upper fasteners (220), at least in part (i.e., alongside the rear lower fasteners (222)), serve to fasten the cage rear panel (208) to a rear face (not shown) of the fan module (202). Further, by way of an example, each rear upper fastener (220) may be implemented using a M3×20 screw (defined by 2.9 millimeter diameter and 20 millimeter length).

In one or many embodiment(s) described herein, the caged fan module (200A, 200B, 200C) includes a quartet (4) of front lower fasteners (214) (e.g., screws) disposed at the lower left and right corners of the cage front panel (206). Specifically, at each said corner and in accommodation of an air dam base tunnel (216) passing through at least a portion of said corner, a pair (2) of the quartet (4) of front lower fasteners (214) may be positioned diagonally from one another (as illustrated in FIG. 2B). Each of said pair (2) of the quartet (4) of front lower fasteners (214) are smaller fasteners that replace a single larger fastener (e.g., similar to a front upper fastener (212)) in order to, at least in part (i.e., alongside the front upper fasteners (212)), serve to fasten the cage front panel (206) to a front face (not shown) of the fan module (202). Further, by way of an example, each front lower fastener (214) may be implemented using a M2×20 screw (defined by 1.9 millimeter diameter and 20 millimeter length).

In one or many embodiment(s) described herein, the caged fan module (200A, 200B, 200C) includes a quartet (4) of rear lower fasteners (222) (e.g., screws) disposed at the lower left and right corners of the cage rear panel (208). Specifically, at each said corner and in accommodation of an air dam base tunnel (216) passing through at least a portion of said corner, a pair (2) of the quartet (4) of rear lower fasteners (222) may be positioned diagonally from one another (as illustrated in FIG. 2C). Each of said pair (2) of the quartet (4) of rear lower fasteners (222) are smaller fasteners that replace a single larger fastener (e.g., similar to a rear upper fastener (220)) in order to, at least in part (i.e., alongside the rear upper fasteners (220)), serve to fasten the cage rear panel (208) to a rear face (not shown) of the fan module (202). Further, by way of an example, each rear lower fastener (222) may be implemented using a M2×20 screw (defined by 1.9 millimeter diameter and 20 millimeter length.

FIG. 3 shows a keyed assembly of a cable sealed, top and bottom plugged air dam base in accordance with one or more embodiments described herein. The cabled sealed, top and bottom plugged air dam base (328) represents a final form of an air dam base (310, also see e.g., 116, FIG. 1) once a transceiver cable (318) is routed through and sealed within said air dam base (310). Further, said keyed assembly includes the following sequence of steps:
1. An air dam base bottom half plug (302) is inserted into an air dam base (310), which is affixed to a bottom panel (not shown) of a chassis (not shown) of a network switch (not shown); the air dam base bottom half plug (302) includes a combination of bottom half plug grooves (304) and bottom half plug tongues (306) spaced evenly along each side thereof, where said bottom half plug grooves and tongues (304, 306) align with corresponding base grooves (312) also spaced evenly along each side of the air dam base (310); the bottom half plug tongues (306) are designed and configured to fit into corresponding base grooves (312) when the air dam base bottom half plug (302) is inserted into the air dam base (310); a width of the air dam base bottom half plug (302) is slighter smaller than a width of the air dam base (310) although their respective heights and lengths match; further, the air dam base bottom half plug (302) also includes a bottom half plug cable channel (308) at its base and along a length thereof, where the bottom half plug cable channel (308) is molded to conform to a bottom half of the cross-section shape of the transceiver cable (318) being routed there-through
2. A bottom plugged air dam base (314) is obtained following insertion of the air dam base bottom half plug (302) into the air dam base (310); said insertion results in multiple bottom tongue and groove joints (316) created through the fitting of the bottom half plug tongues (306) into, and flush with, aligned and corresponding base grooves (312)
3. A transceiver cable (318) (e.g., a simplex or single-strand fiber-optic cable or an Ethernet cable) is routed along the bottom plugged air dam base (314), where the former subsequently rests, or is seated, over the bottom half plug cable channel (308)
4. A cable routed, bottom plugged air dam base (320) is obtained following routing of the transceiver cable (318) along the bottom plugged air dam base (314)
5. An air dam base top half plug (322) is inserted into the cable routed, bottom plugged air dam base (320); the air dam base top half plug (322) includes a number of top half plug tongues (324) along the ends of each side thereof, where said top half plug tongues (324) align with a remainder of the base grooves (312) unoccupied by the bottom half plug tongues (306); a width of the air dam base top half plug (322), similar to the air dam base bottom half plug (302), is slighter smaller than a width of the air dam base (310) although their respective heights and lengths match; further, also like the air dam base bottom half plug (302), the air dam base top half plug (322) further includes a top half plug cable channel (326) at its ceiling and along a length thereof, where the top half plug cable channel (326) is molded to conform to a top half of the cross-section shape of the transceiver cable (318) routed/seated in the cable routed, bottom plugged air dam base (320)
6. A cable sealed, top and bottom plugged air dam base (328) is obtained following insertion of the air dam base top half plug (322) into the cable routed, bottom plugged air dam base (320); said insertion results in multiple top tongue and groove joints (330) created through the fitting of the top half plug tongues (324) into, and flush with, corresponding/aligned and unoccupied base grooves (312); in this final form, the air dam base bottom and top half plugs (302, 322) remain immovable within, and along the length of, the air dam base (310); further, the transceiver cable (318) is secured in place while also sealed, thereby preventing any airflow leakage

While FIG. 3 shows a configuration of components and/or subcomponents, other keyed assembly (300) configurations may be used without departing from the scope of the embodiments described herein.

For example, in one or many embodiment(s) described herein, and rather than routing a transceiver cable (318) with a single cable jacket (as illustrated in FIG. 3), the cable sealed, top and bottom plugged air dam base (328) may instead accommodate the routing of a pair of cables terminated at least at one end by a LC fiber-optic transceiver. LC cabling (not shown) represents a duplex or dual-strand fiber-optic cable, which isolates the two (2) strands of optical fiber in separate cable jackets. In accommodating LC cabling, the bottom and top half plug cable channels (308, 326) would also require changing such that their molding would instead conform to their respective halves of the cross-section shape of the LC cabling.

FIG. 4A shows a fan slot occupation process in accordance with one or more embodiments described herein. The fan slot occupation process (400) pertains to the insertion of transceivers (404), the routing of transceiver cables (420), and the insertion of a caged fan module (418) within a fan slot (414) disposed at the rear of a network switch (see e.g., FIG. 1). To that extent, the fan slot occupation process (400) includes the following sequence of steps:
1. With a caged fan module (418) first removed from a fan slot (414), a transceiver (404), for each rear port (402, also see e.g., 108, FIG. 1) of a pair of rear ports (402) accessible through the fan slot (414), is inserted into said rear port (402)
2. A (compatible) transceiver cable (420), for each inserted transceiver (404) of the pair of inserted transceivers (404), is guided through a cable clamp (406) of a pair of cable clamps (406), where the cable clamp (406) aligns with said inserted transceiver (404) and an air dam base (see e.g., 116, FIG. 1) of a pair of air dam bases within the fan slot (414)
3. Each transceiver cable (420) is then routed through a respective, aligned air dam base (as illustrated and described above in FIG. 3) to obtain a cable sealed, top and bottom plugged air dam base (410) of a pair of cable sealed, top and bottom plugged air dam bases (410)
4. Each transceiver cable (420) is straightened, or held along any axis that facilitates the subsequent insertion of the caged fan module (418)
5. The caged fan module (418) is thereafter inserted into the fan slot (414) such that the air dam base tunnels (see e.g., 216, FIGS. 2A-2C) of the caged fan module (418) glides over the cable sealed, top and bottom plugged air dam bases (410) until the caged fan module (418) is locked into place through the coupling of the chassis fan receptacle (416) with the chassis fan plug (408)

FIG. 4B shows an occupied fan slot in accordance with one or more embodiments described herein. The occupied fan slot (430) reflects a final configuration of components following completion of the fan slot occupation process (illustrated and described above with respect to FIG. 4A).

While the embodiments described herein have been disclosed with respect to a limited number of embodiments, those skilled in the art, having benefit of this disclosure, will appreciate that other embodiments can be devised which do not depart from the scope of the embodiments described herein. Accordingly, the scope of the embodiments described herein should be limited only by the attached claims.

What is claimed is:

1. A network switch, comprising:
a motherboard, comprising:
at least one pair of rear ports disposed at a rear thereof, and comprising:
a left rear port and a right rear port; and
at least one fan slot disposed behind the motherboard and through which the at least one pair of rear ports is accessible.

2. The network switch of claim 1, wherein the at least one fan slot comprises a pair of air dam bases comprising:
a left air dam base disposed along a bottom left side of the at least one fan slot; and
a right air dam base disposed along a bottom right side of the at least one fan slot.

3. The network switch of claim 2, wherein a first transceiver cable is routed through the left air dam base, and wherein a second transceiver cable is routed through the right air dam base.

4. The network switch of claim 3, further comprising:
at least one pair of cable clamps disposed between the motherboard and the at least one fan slot, and comprising:
a left cable clamp aligned with the left air dam base and the left rear port; and
a right cable clamp aligned with the right air dam base and the right rear port.

5. The network switch of claim 4, wherein the first transceiver cable is secured and further routed through the left cable clamp, and wherein the second transceiver cable is secured and further routed through the right cable clamp.

6. The network switch of claim 4, further comprising:
at least one chassis fan plug disposed between the motherboard and the at least one fan slot along one axis, and between the at least one pair of cable clamps along another axis perpendicular to the one axis.

7. The network switch of claim 6, further comprising:
at least one caged fan module, comprising:
a fan module; and
a chassis fan receptacle disposed in front of, and operatively connected to, the fan module,
wherein the chassis fan receptacle is capable of coupling with the at least one chassis fan plug.

8. The network switch of claim 7, wherein the at least one caged fan module glides over the pair of air dam bases, following a routing of a pair of transceiver cables respectively there-through, to occupy the at least one fan slot.

9. The network switch of claim 7, wherein the at least one caged fan module further comprises:
a pair of air dam base tunnels, comprising:
a left air dam base tunnel disposed along a length, and a bottom left side, of the at least one caged fan module; and
a right air dam base tunnel disposed along the length, and a bottom right side, of the at least one caged fan module.

10. The network switch of claim 9, wherein the left air dam base tunnel fits over the left air dam base, and wherein the right air dam base tunnel fits over the left air dam base.

11. The network switch of claim 3, wherein one end of the first transceiver cable couples directly with the left rear port, and wherein one end of the second transceiver cable couples directly with the right rear port.

12. The network switch of claim 11, wherein the left and right rear ports are co-packaged optics (CPO) ports.

13. The network switch of claim 3, wherein one end of the first transceiver cable couples indirectly with the left rear port through a left transceiver inserted into the left rear port, and wherein one end of the second transceiver cable couples indirectly with the right rear port through a right transceiver inserted into the right rear port.

14. The network switch of claim 13, wherein the left and right rear ports are small form-factor pluggable (SFP) ports.

15. The network switch of claim 2, wherein the at least one fan slot further comprises a pair of air dams comprising:
a left air dam erected vertically behind the left air dam base; and
a right air dam erected vertically behind the right air dam base.

16. A method for transforming an air dam base into a cable sealed, top and bottom plugged air dam base, the method comprising:
inserting an air dam base bottom half plug into the air dam base to obtain a bottom plugged air dam base;
routing a transceiver cable through the bottom plugged air dam base to obtain a cable routed, bottom plugged air dam base; and
inserting an air dam base top half plug into the cable routed, bottom plugged air dam base to obtain the cable sealed, top and bottom plugged air dam base.

17. The method of claim 16, wherein the air dam base comprises a set of base grooves lining each side thereof, wherein the air dam base bottom half plug comprises a combination of bottom half plug grooves and bottom half plug tongues lining each side thereof, and wherein the bottom half plug tongues fit into a subset of the set of base grooves as a result of the air dam base bottom half plug being inserted into the air dam base.

18. The method of claim 17, wherein the air dam base top half plug comprises a set of top half plug tongues lining each side thereof, and wherein the set of top half plug tongues fit into a remaining subset of the set of base grooves as a result of the air dam base top half plug being inserted into the cable routed, bottom plugged air dam base.

19. The method of claim 16, wherein the air dam base bottom half plug comprises a bottom half plug cable channel shaped to fit a bottom half of a cross-section of the transceiver cable along a length of the air dam base bottom half plug.

20. The method of claim 16, wherein the air dam base top half plug comprises a top half plug cable channel shaped to fit a top half of a cross-section of the transceiver cable along a length of the air dam base top half plug.
